(19) United States
(12) Patent Application Publication
(10) Pub. No.: US 2026/0133232 A1
(43) Pub. Date: May 14, 2026

(54) DEVICE FOR MEASURING ELECTRICAL PROPERTIES USING WAVEGUIDE TIP ADAPTER

(71) Applicant: Korea Testing Laboratory (KTL), Jinju-si (KR)

(72) Inventors: Tae Seuong SONG, Suwon-si (KR); Sang Wook YOON, Ansan-si (KR); Han Hee LEE, Seoul (KR); Hong Je JANG, Gwangju-si (KR)

(21) Appl. No.: 19/063,365

(22) Filed: Feb. 26, 2025

(30) Foreign Application Priority Data
Nov. 11, 2024 (KR) 10-2024-0159564

(51) Int. Cl. G01R 27/26; G01R 35/00

(52) U.S. Cl. CPC G01R 27/2664; G01R 27/2641; G01R 35/005

(57) ABSTRACT

Proposed is a measurement device. Provided with a waveguide having a first contact surface coming into face-to-face contact with a subject to be measured, the measurement device includes a detachable part provided at the waveguide, the detachable part coming into close contact with the first contact surface, and an extended part extending from the detachable part, wherein the extended part is provided with an extension hole communicating with an original hole provided in the waveguide. The extension hole and the original hole are provided in the same size and the same shape, the extension hole extends in a direction the same as an extension direction of the original hole, and the extension hole is aligned with the original hole.

### CROSS REFERENCE TO RELATED APPLICATION

The present application claims priority to Korean Patent Application No. 10-2024-0159564, filed 11 Nov. 2024, the entire contents of which is incorporated herein for all purposes by this reference.

### BACKGROUND OF THE INVENTION

### Field of the Invention

The present disclosure relates to a device and a method for measuring electrical properties using a waveguide.

### Description of the Related Art

Permittivity measurement methods include a free-space measurement method, a measurement method using a resonator (resonant cavity), and a waveguide measurement method based on resonance.

Recently, the increasing use of high frequencies in various fields such as communications, national defense, and natural sciences using electromagnetic waves has led to an increase in research on the properties of materials in a high-frequency band.

In particular, permittivity is an essential factor when equipment for a high-frequency band is designed, and accurately measuring the permittivity of a dielectric for each frequency band is one of the important tasks.

Loss in a high-frequency band is greater than that in a low-frequency band and equipment for measurement is limited in size in a high-frequency band, so it is difficult to measure the exact permittivity of a dielectric using a permittivity measurement method in the art.

Therefore, permittivity measurement in a millimeter wave band or greater must address these problems to enable accurate measurement.

The foregoing is intended merely to aid in the understanding of the background of the present disclosure, and is not intended to mean that the present disclosure falls within the purview of the related art that is already known to those skilled in the art.

### SUMMARY OF THE INVENTION

The present disclosure is directed to providing a device for measuring electrical properties using a waveguide tip adapter.

There is provided a measurement device provided with a first module or a second module corresponding to a waveguide tip adapter.

Provided with a waveguide having a first contact surface coming into face-to-face contact with a subject to be measured, the measurement device includes:
a detachable part provided at the waveguide, the detachable part coming into close contact with the first contact surface; and an extended part extending from the detachable part, wherein the extended part is provided with an extension hole communicating with an original hole provided in the waveguide.

The extension hole and the original hole may be provided in the same size and the same shape, the extension hole may extend in a direction the same as an extension direction of the original hole, and the extension hole may be aligned with the original hole.

When an end of the waveguide is provided with a flange provided with a screw hole used for coupling with another waveguide, the detachable part may be provided with an attaching-detaching hole matching the screw hole, and the extension hole may be provided to be aligned with the original hole when the attaching-detaching hole is aligned with the screw hole.

An end of the extended part may be provided with a second contact surface coming into face-to-face contact with the subject, in place of the first contact surface, and the second contact surface may be provided to have a second area smaller than a first area of the first contact surface.

The extended part may be provided in the shape of a hollow pipe, a hollow of the extended part may correspond to the extension hole, and a second thickness of a second tube wall surrounding the extension hole at the extended part may be provided less than a thickness of a terminal tube wall surrounding the original hole at an end of the waveguide.

The second tube wall of the extended part may maintain the second thickness from a start point at which extension starts from the detachable part to an end point at which extension ends, and at an end portion of the second tube wall, one surface thereof facing the subject may be provided as a second contact surface coming into face-to-face contact with the subject, and due to a difference between the second thickness of the second tube wall and the thickness of the terminal tube wall, the second contact surface may have a smaller area than the first contact surface has.

When the waveguide includes a pipe part in the shape of a pipe having the original hole as a hollow and a flange provided at an end portion of the pipe part and a thickness of an extension tube wall corresponding to a tube wall surrounding the original hole at the flange is provided greater than a first thickness of a first tube wall surrounding the original hole at the pipe part and one surface of an end of the extension tube wall is provided as the first contact surface, a second thickness of a second tube wall surrounding the extension hole at the extended part may be provided less than the thickness of the extension tube wall.

With the second thickness of the second tube wall provided less than the thickness of the extension tube wall, the second thickness of the second tube wall may be provided equal to or less than the first thickness of the first tube wall.

The detachable part may be provided as a quadrangle.

When a first surface of the detachable part provided as the quadrangle faces the waveguide, the extended part may protrude and extend from a second surface of the detachable part.

One edge of the detachable part corresponding to one side of the quadrangle may be provided perpendicular to an extension direction of the extended part.

The length of the one edge in a direction perpendicular to the extension direction of the extended part and the length of the extended part in the extension direction of the extended part may be provided to satisfy a range from 13:4 to 13:6.

When a first waveguide coming into face-to-face contact with a first surface of the subject is provided and a second waveguide coming into face-to-face contact with a second surface of the subject, a first module and a second module each provided with the detachable part and the extended part may be provided.

The first module may be installed at the first waveguide, and the second module may be installed at the second waveguide.

In place of the first waveguide, the extended part of the first module may come into face-to-face contact with the first surface of the subject.

In place of the second waveguide, the extended part of the second module may come into face-to-face contact with the second surface of the subject.

A guide part that is placed between the first module and the second module in place of the subject and used for calibration of the waveguides may be provided, and a first insertion part into which an end of the extended part of the first module is inserted may be provided at a first surface of the guide part.

A second insertion part into which an end of the extended part of the second module is inserted may be provided at a second surface of the guide part.

A first guide that is placed between the first module and the second module in place of the subject may be provided.

Insertion parts provided recessed may be provided at surfaces of the first guide facing the extended parts of the respective modules.

The insertion parts may be provided in a size and a shape such that ends of the extended parts are insertable.

In the middle of bottom surfaces of the insertion parts, a guide hole in the same size and the same shape as the extension holes may be provided.

In a first surface of the first guide facing the first module and a second surface of the first guide facing the second module, the guide hole may be provided passing through the first and second surfaces of the first guide.

With the first module and the second module inserted into the insertion parts, the length of the guide hole provided from an end of the first module to an end of the second module may be provided to be the length of 0.25 of a wavelength of a measurement signal used to measure permittivity of the subject.

The insertion parts and the guide hole may be provided on a coaxial axis together with the extension hole of the first module and the extension hole of the second module.

A second guide that is placed between the first module and the second module in place of the subject may be provided.

Insertion parts in the form of a groove may be provided at surfaces of the second guide facing the extended parts of the respective modules.

The insertion parts may be provided in a size and a shape such that ends of the extended parts are insertable.

In bottom surfaces of the insertion parts, a guide hole in the same size and the same shape as the extension holes may be not provided.

The insertion parts may be provided on a coaxial axis together with the extension hole of the first module and the extension hole of the second module.

A support part supporting the first module and the second module may be provided.

The support part may include a first support and a second support.

The first support may support the first waveguide or the first module while the first waveguide and the first module are coupled.

The second support may support the second waveguide or the second module while the second waveguide and the second module are coupled.

The first support or the second support may align the extended part of the first module and the extended part of the second module on a coaxial axis during measurement of the subject to be measured.

According to the measurement device of the present disclosure, the waveguide tip adapter (the first module or the second module) having the detachable part and the extended part may be provided at the waveguide.

Conventionally, two waveguides are installed to face each other with a subject therebetween to measure physical characteristics, such as permittivity. For stable and close contact between the waveguides, a plate-shaped flange is formed at an end of each of the waveguides.

It has been found that external noise is introduced and parasitic effect occurs when physical characteristics are measured using the waveguides at which the flanges are formed. After numerous experiments to determine the cause, it was found that parasitic effect is caused by the large contact area between the subject and the flanges.

To solve this problem, it may be considered to form a subject to be in the size of a hole (original hole) through which a signal is transmitted. However, as the frequency increases, the size of a subject must decrease, making it difficult to support the subject in reality. As a solution to this, a method of installing a subject at a jig with an installation hole in the size of the original hole and placing the jig between two waveguides may be considered, but this also has a practical problem that it is difficult to make the subject come into close contact with the waveguides.

In this situation, the present disclosure may provide the first module or the second module of a structure detachably attached to an existing waveguide.

Each module is detachably attached to the waveguide and may form a kind of adapter that comes into direct contact with a subject, in place of the waveguide.

The end portion of the adapter facing the subject may be formed to have a very small contact area compared to the flange of the waveguide.

As a result, the subject is in minimal contact with a measurement means during a measurement process, and through this, it was found that experimental results are output accurately and consistently.

In addition, the present disclosure may enable the length of the original hole through which a signal of the waveguide is transmitted to be extended due to the extended parts. Accordingly, calibration of the waveguide or calibration of the measurement signal needs to be performed anew. The present disclosure facilitates calibration operation by using the first guide and the second guide, which enable the extended parts to be easily aligned.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a schematic diagram illustrating a measurement device according to an embodiment of the present disclosure;

FIG. 2 is a schematic diagram illustrating a measurement device of a comparative embodiment;

FIG. 3 is a schematic diagram illustrating a coupling state of a waveguide and a detachable part;

FIG. 4 is a schematic diagram illustrating a waveguide partially cut off;

FIG. 5 is a schematic diagram illustrating a first guide of a measurement device according to an embodiment of the present disclosure;

FIG. 6 is a schematic diagram illustrating an insertion state of an extended part with respect to a first guide; and

FIG. 7 is a schematic diagram illustrating a second guide of a measurement device according to an embodiment of the present disclosure.

### DETAILED DESCRIPTION OF THE INVENTION

Hereinbelow, exemplary embodiments of the present disclosure will be described in detail with reference to the accompanying drawings such that the present disclosure can be easily embodied by those skilled in the art to which this present disclosure belongs. However, the present disclosure may be embodied in various different forms and should not be limited to the embodiments set forth herein. Further, in order to clearly explain the present disclosure, portions that are not related to the present disclosure are omitted in the drawings, and like reference numerals designate like elements throughout the specification.

In the present specification, a redundant description of the same element will be omitted.

In addition, in the present specification, it will be understood that when an element is referred to as being “coupled” or “connected” to another element, it can be directly coupled or connected to the other element or intervening elements may be present therebetween. In contrast, in the present specification, it will be understood that when an element is referred to as being “directly coupled” or “directly connected” to another element, there are no intervening elements present.

In addition, the terms used in the present specification are merely used to describe particular embodiments, and are not intended to limit the present disclosure.

In addition, in the present specification, the singular forms “a”, “an”, and “the” are intended to include the plural forms as well, unless the context clearly indicates otherwise.

In addition, it will be understood that terms such as “including”, “having”, etc. are intended to indicate the existence of the features, numbers, steps, actions, elements, parts, or combinations thereof disclosed in the specification, and are not intended to preclude the possibility that one or more other features, numbers, steps, actions, elements, parts, or combinations thereof may exist or may be added.

In addition, in the present specification, the term “and/or” includes a combination of a plurality of items or any one of a plurality of terms. In the present specification, the expression “A or B” may include “A”, “B”, or “both A and B”.

In addition, in the present specification, well-known functions and constructions that may obscure the gist of the present disclosure will not be described.

A measurement device of the present disclosure may include an adapter (corresponding to a first module or a second module) that is further provided at a waveguide c used for measuring a subject 90 to be measured. Accordingly, the present disclosure may be referred to as an “adapter” or a “pin adapter”.

The waveguide c may have a first contact surface 31 to be in face-to-face contact with the subject 90 to be measured. The present disclosure may propose a measurement device capable of minimizing a phenomenon in which a measurement result contains external noise or parasitic effect due to the first contact surface 31. A cable 40 for inputting and outputting measurement signals to and from the waveguide may be connected to the waveguide.

The measurement device described in the present specification may include the first module a1 or the second module a2 or both. Depending on a case, the concept of a measurement device may be extended to include the waveguide c. Specifically, the measurement device may further include a first waveguide c1 at which the first module a1 is provided, or the measurement device may further include a second waveguide c2 at which the second module a2 is provided.

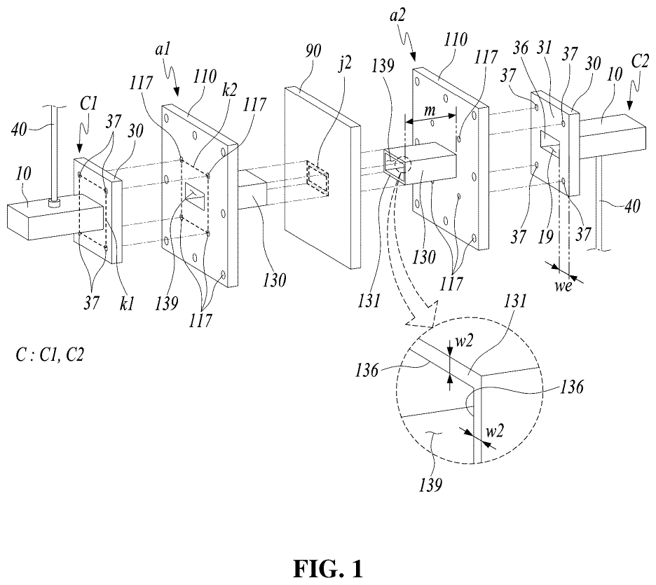

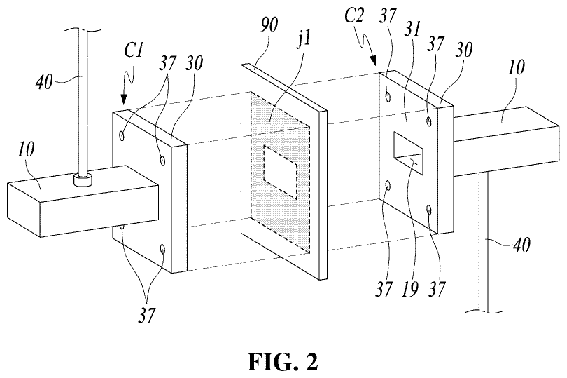

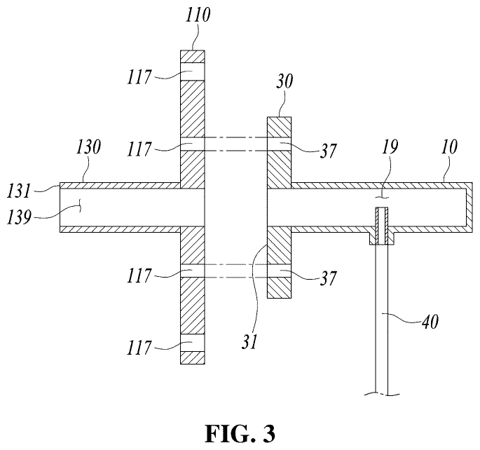

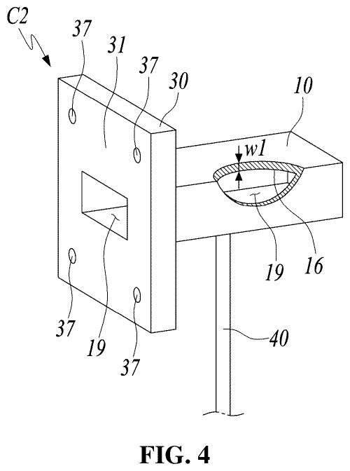

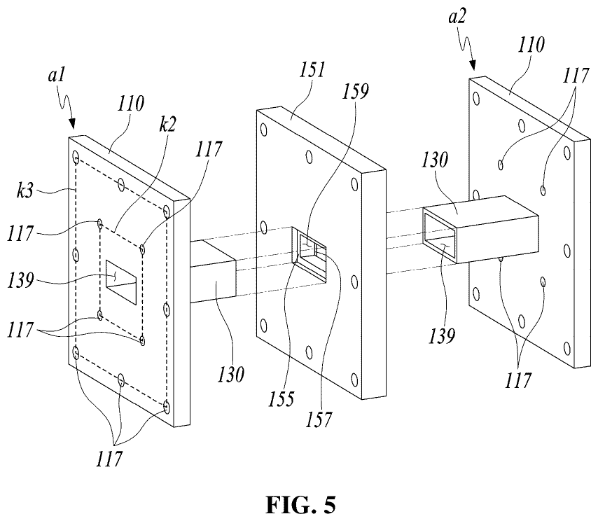

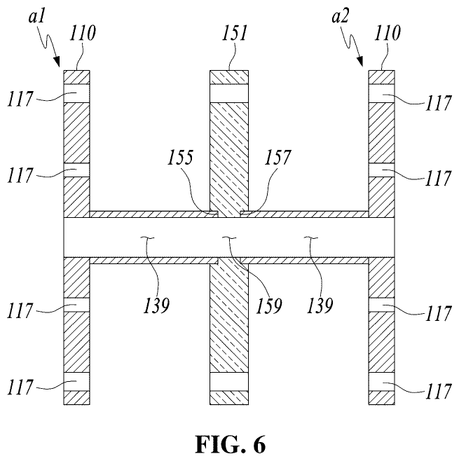

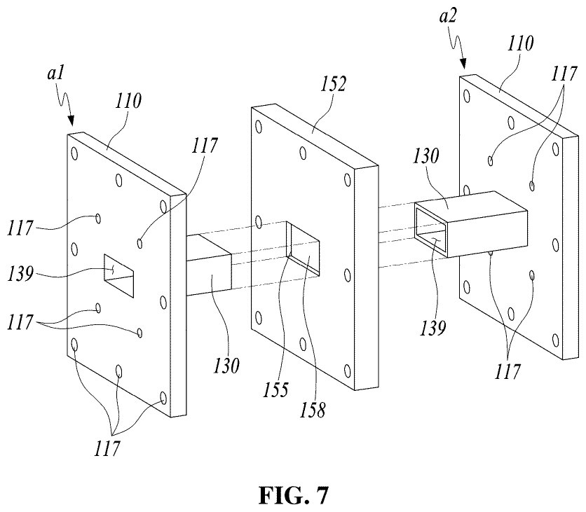

FIG. 1 is a schematic diagram illustrating a measurement device according to an embodiment of the present disclosure. FIG. 2 is a schematic diagram illustrating a measurement device of a comparative embodiment. FIG. 3 is a schematic diagram illustrating a coupling state of a waveguide and a detachable part 110. FIG. 4 is a schematic diagram illustrating a waveguide partially cut off. FIG. 5 is a schematic diagram illustrating a first guide 151 of a measurement device according to an embodiment of the present disclosure. FIG. 6 is a schematic diagram illustrating an insertion state of an extended part 130 with respect to a first guide 151. FIG. 7 is a schematic diagram illustrating a second guide 152 of a measurement device according to an embodiment of the present disclosure.

The measurement device shown in FIG. 1 may include a detachable part 110 and an extended part 130.

The detachable part 110 may be provided at the waveguide, the detachable part coming into close contact with the first contact surface 31 of the waveguide. When necessary, the detachable part 110 may be formed in a detachable structure that is removable from the waveguide.

For example, when a screw hole 37 is formed in the first contact surface 31 of the waveguide, an attaching-detaching hole 117 corresponding to the screw hole 37 may be formed in the detachable part 110. When the screw hole 37 of the waveguide and the attaching-detaching hole 117 of the detachable part 110 are coupled by a screw, the detachable part 110 may be provided with respect to the waveguide. When the screw is loosened, the detachable part 110 may be removed from the waveguide.

The extended part 130 may protrude and extend from the detachable part 110. An extension hole 139 communicating with an original hole 19 formed in the waveguide may be formed in the extended part 130.

The extension hole 139 and the original hole 19 may be formed in the same size and the same shape. In addition, the extension hole 139 and the original hole 19 may extend in the same direction. In addition, the extension hole 139 and the original hole 19 may be aligned with each other to exactly match each other. The extended part 130 having the above characteristics may have the outward appearance of further extending the length of the waveguide beyond its original length.

The waveguide may be placed facing another waveguide with the subject 90 to be measured in between. Herein, in order to align and fix the waveguides facing each other, an end of the waveguide may be provided with a flange 30 in which the screw hole 37 is formed for coupling with the other waveguide.

The attaching-detaching hole 117 matched with the screw hole 37 formed in the flange 30 may be formed in the detachable part 110.

The extension hole 139 may be formed to be aligned with the original hole 19 when the attaching-detaching hole 117 of the detachable part 110 is aligned with the screw hole 37 of the flange 30.

For example, in FIG. 1, the screw hole 37 of the flange 30 may be formed at each vertex of a first quadrangle k1, which is imaginary. Herein, the original hole 19 may be formed in the center of the first quadrangle k1.

Correspondingly, the attaching-detaching hole 117 of the detachable part 110 may also be formed at each vertex of a second quadrangle k2, which is imaginary. Herein, the second quadrangle k2 and the first quadrangle k1 may be formed in the same size and the same shape. The extension hole 139 formed in the extended part 130 may be formed in the center of the second quadrangle k2. Through this, the center of the extension hole 139 and the center of the original hole 19 may be placed on a coaxial axis going through the center of the first quadrangle k1 and the center of the second quadrangle k2. As a result, matching the screw hole 37 and the attaching-detaching hole 117 with each other may provide the condition in which the original hole 19 and the extension hole 139 are naturally placed on a coaxial axis.

According to the present embodiment, the user only needs to align or couple the attaching-detaching hole 117 of the detachable part 110 with the screw hole 37 of the flange 30, and then the extension hole 139 of the detachable part 110 and the original hole 19 of the waveguide may be naturally aligned.

In the meantime, attaching-detaching holes 117 in various sizes formed at positions outside the outline of the second quadrangle k2 may be added to enable coupling with flanges 30 of various specifications. For example, in the embodiment of FIG. 5, a plurality of attaching-detaching holes 117 may be further formed along the outline of the third quadrangle k3, which is imaginary, of the size including the second quadrangle k2 inside. The attaching-detaching holes 117 at positions corresponding to the third quadrangle k2 may be used for coupling with the flange 30 in which the screw holes 37 are formed.

In place of the first contact surface 31, a second contact surface 131 may be formed at an end of the extended part 130 to come into face-to-face contact with the subject 90. According to the present disclosure, the first contact surface 31, which is originally to be in contact with the subject, may come into face-to-face contact with the detachable part 110. Instead, the second contact surface 131 formed at the extended part 130 may come into contact with the subject 90.

The second contact surface 131 may be formed to have a second area j2 that is smaller than a first area j1 of the first contact surface 31.

According to the measurement device of the present disclosure, the detachable part 110 and the extended part 130 may be placed between the waveguide and the subject 90. Accordingly, the waveguide and the subject 90 may be placed spaced apart from each other by the detachable part 110 and the extended part 130. Thus, in place of the first contact surface 31 corresponding to one surface of the flange 30 which originally comes into contact with the subject 90 as shown in FIG. 2, the second contact surface 131 corresponding one surface of the extended part 130 may come into contact with the subject 90 as shown in FIG. 1. Herein, the extended part 130 may be formed such that the second area j2 of the second contact surface 131 is smaller than the first area j1 of the first contact surface 31.

Specifically, the extended part 130 may be formed in the shape of a hollow pipe. Herein, the hollow of the extended part 130 may correspond to the extension hole 139.

A second thickness w2 of a second tube wall 136 surrounding the extension hole 139 at the extended part 130 may be formed to be less than the thickness of a terminal tube wall surrounding the original hole 19 at the end of the waveguide.

The second thickness w2 of the second tube wall 136 may determine the width or length of the second contact surface 131 of the extended part 130. The thickness of the terminal tube wall may determine the width or length of the first contact surface 31 formed at an end portion of the waveguide. Therefore, when the second thickness w2 is formed to be less than the thickness of the terminal tube wall, the second area j2 corresponding to the area of the second contact surface 131 may be smaller than the first area j1 corresponding to the area of the first contact surface 31.

If a flange 30 exists, the flange 30 may correspond to the end portion of the waveguide. In this case, the waveguide c may include a pipe part 10 in the shape of a pipe having the original hole 19 as a hollow, and the flange 30 formed at an end portion of the pipe part 10.

If a flange 30 does not exist, one end portion of the pipe part 10 may correspond to the end portion of the waveguide.

In order to further reduce parasitic effect, the second tube wall 136 of the extended part 130 may maintain the second thickness w2 from a start point at which extension starts from the detachable part 110 to an end point at which extension ends. Described from another perspective, when a first surface of the detachable part 110 faces the waveguide c, the extended part 130 may protrude and extend from a second surface of the detachable part 110. Herein, the second tube wall 136 may be maintained in the second thickness w2 throughout the entire section from the second surface of the detachable part 110 to an end of the second tube wall 136.

At an end portion of the second tube wall 136, one surface thereof facing the subject 90 may form the second contact surface 131 that comes into face-to-face contact with the subject 90.

Due to the difference between the second thickness of the second tube wall 136 and the thickness of the terminal tube wall, the second contact surface 131 may have a smaller area (the second area j2) than the first contact surface 31 has.

To describe the above embodiment again, the thickness we of an extension tube wall 36 corresponding to the tube wall surrounding the original hole 19 in the flange 30 may be formed greater than a first thickness w1 of a first tube wall 16 surrounding the original hole 19 in the pipe part 10. When one surface of an end of the extension tube wall 36 forms the first contact surface 31, the second thickness w2 of the second tube wall 136 surrounding the extension hole 139 in the extended part 13 may be formed less than the thickness we of the extension tube wall 36.

When the second thickness w2 of the second tube wall 136 is formed less than the thickness we of the extension tube wall 36, the second thickness w2 of the second tube wall 136 may be formed equal to or less than the first thickness w1 of the first tube wall 16 of the pipe part 10. Accordingly, even if it is assumed that the pipe part 10 comes into face-to-face contact with the subject 90 directly without the flange 30, the extended part 130 may come into contact with the subject 90 with a smaller area, and may dramatically reduce the introduction of noise and the generation of parasitic effect.

In the meantime, the issue of how long the extended part 130 should be set to extend needs to be addressed.

For example, the detachable part 110 may be formed in the shape of a quadrangular plate, for example, a square plate.

When the first surface of the detachable part 110 formed in a quadrangular shape faces the waveguide, the extended part 130 may protrude and extend from the second surface of the detachable part 110. Herein, one edge of the detachable part 110 corresponding to one side of the quadrangle may be formed perpendicular to the extension direction of the extended part 130. Overall, the extended part 130 may be formed perpendicular to the quadrangular plate (plane) forming the detachable part 110.

In the direction perpendicular to the extension direction of the extended part 130, the length of one edge of the detachable part 110 may be defined as a first length (the length of one side of the quadrangle). In the extension direction of the extended part 130, the length of the extended part may be defined as a second length. Herein, the first length and the second length may be formed to satisfy a range from 13:4 to 13:6. In addition, the first length and the second length may have a perpendicular relationship.

Preferably, when the first length is 13 (for example, 6.5 cm), the second length is 5 (for example, 2.5 cm). Experimentally, it was shown that this length relationship caused the least parasitic effect regardless of the frequency or wavelength of the measurement signal used to measure the permittivity of the subject.

The first waveguide c1 coming into face-to-face contact with a first surface of the subject 90 may be provided, and the second waveguide c2 coming into face-to-face contact with a second surface of the subject 90 may be provided.

The first module a1 and the second module a2 each provided with the detachable part 110 and the extended part 130 may be provided.

The first module a1 may be installed at the first waveguide c1. The second module a2 may be installed at the second waveguide c2.

In place of the first waveguide c1, the extended part 130 of the first module a1 may come into face-to-face contact with the first surface of the subject 90. In place of the second waveguide c2, the extended part 130 of the second module a2 may come into face-to-face contact with the second surface of the subject 90.

In such a situation, a guide part 151 and 152 that is placed between the first module a1 and the second module a2 in place of the subject 90 and used for calibration of the waveguide may be provided.

The guide part 151 and 152 may be provided with insertion parts 155 and 157 into which the extended parts 130 of the respective modules a1 and a2 are inserted.

For example, a first insertion part 155 into which an end of the extended part 130 of the first module a1 is inserted may be formed at a first surface of the guide part 151 and 152. A second insertion part 157 into which an end of the extended part 130 of the second module a2 is inserted may be formed at a second surface of the guide part 151 and 152.

According to the first insertion part 155 and the second insertion part 157, alignment between the first module a1, the second module a2, and the guide part 151 and 152 may be naturally achieved.

The first insertion part may include a groove formed in the first surface of the guide part.

An end of the extended part of the first module may be inserted into the first insertion part to be in close contact with an edge of the bottom surface of the first insertion part. For example, the extended part of the first module may be inserted into the first insertion part until physically interfered with by the bottom surface of the first insertion part.

The second insertion part may include a groove formed in the second surface of the guide part.

An end of the extended part of the second module may be inserted into the second insertion part to be in close contact with an edge of the bottom surface of the second insertion part. For example, the extended part of the second module may be inserted into the second insertion part until physically interfered with by the bottom surface of the second insertion part.

Herein, the middle of the bottom surface of the first insertion part and the middle of the bottom surface of the second insertion part may be formed flat in isolation from each other. In this case, the space between the bottom surface of the first insertion part and the bottom surface of the second insertion part may be maintained in a closed state, for example, with a partition wall formed.

Alternatively, in the middle of the bottom surface of the first insertion part and the middle of the bottom surface of the second insertion part, a guide hole may be formed passing through the surfaces.

For example, the guide part may include the first guide 151 in which the guide hole 159 is formed, and the second guide 152 in which the guide hole 159 is not formed.

Referring to FIGS. 5 and 6, the first guide 151 that is placed between the first module and the second module in place of the subject 90 may be provided.

The insertion parts 155 and 157 formed recessed may be provided at the surfaces of the first guide 151 facing the extended parts 130 of the respective modules. The insertion parts may include the first insertion part 155 facing the first module a1 and the second insertion part 157 facing the second module a2.

The insertion parts may be formed in a size and shape such that the ends of the extended parts 130 are insertable. The guide hole 159 having the same size and the same shape as the extension holes 139 may be formed in the middle of the bottom surfaces 158 of the insertion parts.

In a first surface of the first guide 151 facing the first module a1 and a second surface of the first guide 151 facing the second module, the guide hole 159 may be formed passing through the surfaces. With the first module a1 and the second module a2 inserted into the insertion parts, the length of the guide hole 159 formed from an end of the first module a1 to an end of the second module a2 may be formed to be the length of 0.25 of the wavelength of the measurement signal used to measure the permittivity of the subject 90.

The insertion parts and the guide hole 159 may be formed on a coaxial axis together with the extension hole 139 of the first module a1 and the extension hole 139 of the second module a2.

According to the first guide 151, compared to the space originally formed by the original hole 19 of the waveguide, the space by the extension hole 139 of the first module a1, the space by the extension hole 139 of the second module a2, and the space by the guide hole 159 may be added. In this state, the measurement standard of the waveguide may be subjected to first calibration. First calibration may simulate a situation in which the measurement signal of the waveguide passes intactly from a first end of the subject 90 to a second end thereof.

Referring to FIG. 7, the second guide 152 that is placed between the first module a1 and the second module a2 in place of the subject 90 may be provided.

The insertion parts 155 and 157 in the form of a groove may be provided at the surfaces of the second guide 152 facing the extended parts 130 of the respective modules. The insertion parts may include the first insertion part 155 facing the first module a1 and the second insertion part 157 facing the second module a2.

The insertion parts may be formed in a size and shape such that the ends of the extended parts 130 are insertable. The guide hole 159 having the same size and the same shape as the original holes 19 may be not formed in the bottom surfaces 158 of the insertion parts. For example, the bottom surfaces 158 of the insertion parts formed at the second guide 152 may be maintained in a closed state.

The insertion parts may be formed on a coaxial axis together with the extension hole 139 of the first module and the extension hole 139 of the second module. According to the present embodiment, the extended part 130 of the first module a1 inserted into the first insertion part 155 and the extended part(130) of the second module a2 inserted into the second insertion part 157 may be interrupted from each other by the bottom surfaces 158 closed at the insertion part.

According to the second guide 152, compared to the space originally formed by the original hole 19 of the waveguide, the space by the extension hole 139 of the first module a1 and the space by the extension hole 139 of the second module a2 may be added with the middle interrupted by the second guide 152. In this state, the measurement standard of the waveguide may be subjected to second calibration. Second calibration may simulate a situation in which the measurement signal of the waveguide is completely blocked from being transmitted from the first end of the subject 90 to the second end thereof.

In the case of the first guide 151 or the second guide 152, the insertion parts into which end portions of the extended parts 130 are inserted are formed, so the alignment problem of the extended parts 130 may be alleviated.

However, when the subject 90 to be measured is not formed with a groove that functions as the insertion part, alignment using the groove is impossible.

In this case, it is preferable to simply have means for supporting each module so that the first module a1 placed on one side of the subject 90 and the second module a2 placed another side of the subject 90 are accurately aligned with each other.

For example, a support part supporting the first module a1 and the second module a2 may be provided.

The support part may include a first support and a second support.

The first support may support the first waveguide or the first module while the first waveguide and the first module are coupled.

The second support may support the second waveguide or the second module while the second waveguide and the second module are coupled.

The first support or the second support may align the extended part 130 of the first module a1 and the extended part 130 of the second module a2 on a coaxial axis during measurement of the subject 90 to be measured.

Although preferred embodiments of the present disclosure have been described for illustrative purposes, those skilled in the art will appreciate that various modifications, additions and substitutions are possible, without departing from the scope and spirit of the disclosure as disclosed in the accompanying claims.

What is claimed is:

1. A measurement device, comprising:
provided with a waveguide having a first contact surface coming into face-to-face contact with a subject to be measured,
a detachable part provided at the waveguide, the detachable part coming into close contact with the first contact surface; and
an extended part extending from the detachable part,
wherein the extended part is provided with an extension hole communicating with an original hole provided in the waveguide.

2. The measurement device of claim 1, wherein the extension hole and the original hole are provided in the same size and the same shape,
the extension hole extends in a direction the same as an extension direction of the original hole, and
the extension hole is aligned with the original hole.

3. The measurement device of claim 1, wherein when an end of the waveguide is provided with a flange provided with a screw hole used for coupling with another waveguide,
the detachable part is provided with an attaching-detaching hole matching the screw hole, and
the extension hole is provided to be aligned with the original hole when the attaching-detaching hole is aligned with the screw hole.

4. The measurement device of claim 1, wherein an end of the extended part is provided with a second contact surface coming into face-to-face contact with the subject, in place of the first contact surface, and
the second contact surface is provided to have a second area smaller than a first area of the first contact surface.

5. The measurement device of claim 1, wherein the extended part is provided in the shape of a hollow pipe,
a hollow of the extended part corresponds to the extension hole, and
a second thickness of a second tube wall surrounding the extension hole at the extended part is provided less than a thickness of a terminal tube wall surrounding the original hole at an end of the waveguide.

6. The measurement device of claim 5, wherein the second tube wall of the extended part maintains the second thickness from a start point at which extension starts from the detachable part to an end point at which extension ends,
at an end portion of the second tube wall, one surface thereof facing the subject is provided as a second contact surface coming into face-to-face contact with the subject, and
due to a difference between the second thickness of the second tube wall and the thickness of the terminal tube wall, the second contact surface has a smaller area than the first contact surface has.

7. The measurement device of claim 1, wherein when the waveguide includes a pipe part in the shape of a pipe having the original hole as a hollow and a flange provided at an end portion of the pipe part and a thickness of an extension tube wall corresponding to a tube wall surrounding the original hole at the flange is provided greater than a first thickness of a first tube wall surrounding the original hole at the pipe part and one surface of an end of the extension tube wall is provided as the first contact surface,
a second thickness of a second tube wall surrounding the extension hole at the extended part is provided less than the thickness of the extension tube wall.

8. The measurement device of claim 7, wherein with the second thickness of the second tube wall provided less than the thickness of the extension tube wall, the second thickness of the second tube wall is provided equal to or less than the first thickness of the first tube wall.

9. The measurement device of claim 1, wherein the detachable part is provided as a quadrangle,
when a first surface of the detachable part provided as the quadrangle faces the waveguide, the extended part protrudes and extends from a second surface of the detachable part,
one edge of the detachable part corresponding to one side of the quadrangle is provided perpendicular to an extension direction of the extended part, and
the length of the one edge in a direction perpendicular to the extension direction of the extended part and the length of the extended part in the extension direction of the extended part are provided to satisfy a range from 13:4 to 13:6.

10. The measurement device of claim 1, wherein when a first waveguide coming into face-to-face contact with a first surface of the subject is provided and a second waveguide coming into face-to-face contact with a second surface of the subject,
a first module and a second module each provided with the detachable part and the extended part are provided,
the first module is installed at the first waveguide,
the second module is installed at the second waveguide,
in place of the first waveguide, the extended part of the first module comes into face-to-face contact with the first surface of the subject, and
in place of the second waveguide, the extended part of the second module comes into face-to-face contact with the second surface of the subject.

11. The measurement device of claim 10, wherein a guide part that is placed between the first module and the second module in place of the subject and used for calibration of the waveguides is provided,
a first insertion part into which an end of the extended part of the first module is inserted is provided at a first surface of the guide part, and
a second insertion part into which an end of the extended part of the second module is inserted is provided at a second surface of the guide part.

12. The measurement device of claim 11, wherein the first insertion part includes a groove provided in the first surface of the guide part,
the end of the extended part of the first module is inserted into the first insertion part to be in close contact with an edge of a bottom surface of the first insertion part,
the second insertion part includes a groove provided in the second surface of the guide part,
the end of the extended part of the second module is inserted into the second insertion part to be in close contact with an edge of a bottom surface of the second insertion part, and
the middle of the bottom surface of the first insertion part and the middle of the bottom surface of the second insertion part are provided flat in isolation from each other, or in the middle of the bottom surface of the first insertion part and in the middle of the bottom surface of the second insertion part, a guide hole is provided passing through the bottom surfaces.

13. The measurement device of claim 10, wherein a first guide that is placed between the first module and the second module in place of the subject is provided,
insertion parts provided recessed are provided at surfaces of the first guide facing the extended parts of the respective modules,
the insertion parts are provided in a size and a shape such that ends of the extended parts are insertable,
in the middle of bottom surfaces of the insertion parts, a guide hole in the same size and the same shape as the extension holes is provided,
in a first surface of the first guide facing the first module and a second surface of the first guide facing the second module, the guide hole is provided passing through the first and second surfaces of the first guide,
with the first module and the second module inserted into the insertion parts, the length of the guide hole provided from an end of the first module to an end of the second module is provided to be the length of 0.25 of a wavelength of a measurement signal used to measure permittivity of the subject, and
the insertion parts and the guide hole are provided on a coaxial axis together with the extension hole of the first module and the extension hole of the second module.

14. The measurement device of claim 10, wherein a second guide that is placed between the first module and the second module in place of the subject is provided,
insertion parts in the form of a groove are provided at surfaces of the second guide facing the extended parts of the respective modules,
the insertion parts are provided in a size and a shape such that ends of the extended parts are insertable,
in bottom surfaces of the insertion parts, a guide hole in the same size and the same shape as the extension holes is not provided, and
the insertion parts are provided on a coaxial axis together with the extension hole of the first module and the extension hole of the second module.

15. The measurement device of claim 10, wherein a support part supporting the first module and the second module is provided,
the support part includes a first support and a second support,
the first support supports the first waveguide or the first module while the first waveguide and the first module are coupled,
the second support supports the second waveguide or the second module while the second waveguide and the second module are coupled, and
the first support or the second support aligns the extended part of the first module and the extended part of the second module on a coaxial axis during measurement of the subject to be measured.
